(19) United States
(12) Patent Application Publication
(10) Pub. No.: US 2026/0305440 A1
(43) Pub. Date: Oct. 1, 2026

(54) ELECTRONIC COMPONENT ASSEMBLY AND METHOD OF MANUFACTURE

(71) Applicant: THALES, MEUDON (FR)

(72) Inventors: Damien CHALAVOUX, VALENCE (FR); Bertrand LEVERRIER, VALENCE (FR); Serge PARBAUD, Saint Marcel les Valence (FR)

(21) Appl. No.: 19/476,123

(22) PCT Filed: Apr. 22, 2024
(86) PCT No.: PCT/EP2024/060890

§ 371 Date: Oct. 16, 2025

(30) Foreign Application Priority Data
Apr. 28, 2023 (FR) 2304347

(51) Int. Cl. H10W 72/20

(52) U.S. Cl. CPC H10W 72/234

(57) ABSTRACT

A microelectronic assembly includes a microelectronic component, a support and a set of attachment members fixing together the microelectronic component on the support, each attachment member including a conductive bead fixed to the microelectronic component by a first adhesion material and to the support by a second adhesion material, such that, for at least one of the attachment members, a central area of the surface of the conductive bead considered along an axis transverse to the assembly is bare or partially or totally covered by a layer of the first adhesion material and/or a layer of the second adhesion material having a respective thickness of at most 10 nm.

### CROSS-REFERENCE TO RELATED APPLICATIONS

This application is a National Stage of International patent application PCT/EP2024/060890, filed on Apr. 22, 2024, which claims priority to foreign French patent application No. FR 2304347, filed on Apr. 28, 2023, the disclosures of which are incorporated by reference in their entireties.

### FIELD OF THE INVENTION

The invention relates to assemblies of electronic components, and relates notably to system-in-package assemblies.

### BACKGROUND

Microelectronic devices such as semiconductor chips require a large number of electrical connections in a small area. For example, a complex semiconductor chip may include hundreds of contacts for signal inputs and outputs and for electrical power supply, all within an area of a few cm². These contacts must be reliably connected to the corresponding contact pads on a substrate such as a chip carrier, a circuit board or a multi-chip module. The connection between the chip and the substrate must meet numerous, often conflicting, requirements and objectives.

Notably, it must be both inexpensive and very reliable. It should only require a minimum surface area on the substrate. Ideally, the connected chip must be seated in a zone of the substrate approximately equal to that of the chip itself. The connections must be robust and capable of withstanding repeated temperature changes in the chip and the substrate, as well as the associated differential thermal expansions and contractions of the chip and the substrate. Indeed, since the coefficient of expansion of the electronic components is lower than the carrier substrate, temperature variations result in relative displacements. Thus, the connections require the use of a flexible mechanical interface resistant to displacement.

In addition, the connection systems should not impose unusual or costly requirements in the manufacture of the chip or the substrate. It is desirable for the connection system to facilitate testing of the chip and the connection system itself, before the chip is finally assembled on the substrate. Finally, three-dimensional system-in-package assemblies require the spaces between the cards to be controlled accurately and repeatably.

All these considerations, taken together, represent a formidable technical challenge. These considerations are present, to a greater or lesser degree, in other connections used in microelectronic devices such as, for example, connections between substrates or circuit boards.

To this end, it is known to use soldering and/or adhesive bonding techniques, with or without intermediate elements between the parts to be bonded.

Electrically conductive epoxy adhesives are conventionally used as the adhesive to bond the electronic components to the substrates in in-package systems. Epoxy adhesives are applied to solder pads on the substrate. The electronic components are then placed on the solder pads and the assembly is heated to cure the epoxy adhesive and create a solid link between the electronic components and the substrate.

The adhesives can also be applied to reinforce the bonding of the solder joints, notably in the context of microelectronic components with a large-area chip on an organic substrate. For this purpose, an adhesive (referred to as underfill) is usually applied after the chip has been soldered to the substrate, and is injected into the space between the chip and the substrate using a syringe or a robot. It is then cured by heating or exposure to UV light, thus creating a strong and resistant layer between the chip and the substrate. Nevertheless, such bonding makes it impossible to repair the assembly.

Soldering assembly techniques that use columns or balls, in which the electronic components are bonded to the columns or balls bonded to a substrate, are also known. The metal columns are usually copper alloy, but can also be gold alloy for high-temperature applications. The columns are notably made of Pb90Sn10 to ensure reliable assembly. The balls can be made of a fusible alloy, ceramic or comprise a rigid or flexible polymer core covered with a metal sphere, notably copper. The assembly is accomplished by soldering using a solder paste, which is placed on the columns or balls and heated to form solder joints between the columns and solder pads on the substrate. However, the use of lead will no longer be possible when the exemptions from the European Union's Restriction of Hazardous Substances (RoHS) directive concerning lead alloys used in soldering high-performance electronic components for space, military and medical applications are discontinued.

Document U.S. Pat. No. 6,204,455 describes the use of hollow balls inserted into openings in a dielectric sheet to prevent the solder from completely covering the ball and to preserve its flexibility in the dielectric sheet. This improves deformation and therefore resistance to temperature variations. Nevertheless, this assembly method has a high production cost and is difficult to implement. It also requires the balls to be handled frequently prior to assembly.

There is therefore a need for an assembly of electronic components that provides excellent resistance to the relative displacements of said components as well as to temperature variations, while reducing production costs. There is also a need for an assembly method that is not specific to the use of adhesive or soldering, and that allows the assembly to be repaired if necessary.

### SUMMARY OF THE INVENTION

For this purpose, the invention relates to a microelectronic assembly comprising a microelectronic component, a carrier and a set of attachment members bonding the microelectronic component to the carrier, each attachment member comprising a conductive ball bonded to the microelectronic component by a first adhesion material and to the carrier by a second adhesion material, wherein for at least one of the attachment members a central zone of the surface of the conductive ball considered along an axis transverse to the assembly is bare or partially or completely covered by a layer of the first adhesion material and/or a layer of the second adhesion material with a respective thickness of not more than 10 nm.

The microelectronic assembly according to the invention advantageously uses little adhesion material, thus reducing production costs, while increasing the stress resistance of the attachment members. Thus, the reduced quantity of adhesion material used compared with the prior art results in a thin covering, or no covering, of the central zone of the balls, making the attachment members more flexible and thus limiting the mechanical stresses of the assembly. Notably, the central third of each ball is thinly covered, or even bare. In addition, the distribution of adhesion materials over the balls is obtained without a fusible alloy and without the help of holding devices, such as a dielectric sheet, simplifying the production of the assembly. Finally, the assembly according to the invention can be easily disassembled without damaging the components, allowing them to be repaired or replaced.

According to one embodiment of the invention, the microelectronic component forms the upper portion of the assembly and the carrier forms the lower portion of the assembly, wherein for at least one of the attachment members:
at least 95% of the volume of the first adhesion material is located between the microelectronic component and the upper third of the height of the conductive ball considered along an axis transverse to the assembly, and
at least 95% of the volume of the second adhesion material is located between the carrier and the lower third of the height of the conductive ball considered along an axis transverse to the assembly.

According to one embodiment of the invention, for at least one of the attachment members, the first adhesion material comprises a constriction arranged to face the top of the conductive ball and the second adhesion material comprises a constriction arranged to face the base of the conductive ball, the top and the base of the conductive ball being considered along an axis transverse to the assembly.

According to one embodiment of the invention, the microelectronic component forms the upper portion of the assembly and the carrier forms the lower portion of the assembly, wherein for at least one of the attachment members the volume of the first and second adhesion materials corresponds respectively to the volume of a truncated cone comprising a recess. Notably, said truncated cone has a base having a diameter equal to the diameter of the conductive ball and a height of one third of the diameter of said conductive ball and said recess having the shape of a spherical cap having a height of one third of the diameter of the conductive ball.

According to one embodiment of the invention, for at least one of the attachment members, the conductive ball comprises a hollow copper sphere covered with a layer of nickel, preferably a layer of medium-phosphorus nickel, more preferably the phosphorus content is less than 15%.

Notably, the copper sphere has a thickness of less than 100 μm, in particular less than or equal to 50 μm, more notably from 15 μm to 20 μm.

Notably, the nickel layer has a thickness of less than 10 μm, preferably 4 μm to 7 μm.

According to one embodiment of the invention, for at least one of the attachment members, the conductive ball comprises a coating of a material selected from the group consisting of gold, silver, platinum, palladium and an alloy of several of these materials.

The invention also relates to a method of bonding a microelectronic component to a carrier using attachment members of a microelectronic assembly as defined above, the microelectronic component and the carrier each comprising a plurality of connection pads, the method comprising the following steps:
a) a first deposition of a first adhesion material on each pad of the microelectronic component and of a second adhesion material on each corresponding pad of the carrier,
b) a second deposition of a conductive ball on the second adhesion material of each corresponding pad of the carrier,
c) aligning the pads of the microelectronic component with the corresponding pads of the carrier, and bringing the first adhesion materials of each pad of the microelectronic component into contact with the conductive balls,
d) suitably heating and then suitably cooling the assembly to form the attachment members by shaping and curing the first and second adhesion materials, thereby bonding the microelectronic component to the carrier, wherein in the first deposition step a), for at least one of the attachment members the deposited volume of the first and second adhesion materials on the pads is adjusted so that in the heating step d) a central zone of the surface of the conductive ball considered along an axis transverse to the assembly is bare or partially or completely covered by a layer of the first adhesion material and/or a layer of the second adhesion material with a respective thickness of not more than 10 nm.

According to one embodiment of the invention, for at least one of the attachment members the deposited volume of the first and second adhesion materials on the pads corresponds to the volume of a truncated cone comprising a recess, said truncated cone preferably has a base having a diameter equal to the diameter of the conductive ball and a height one third of the diameter of said conductive ball and said recess being shaped as a spherical cap having a height that is one third of the diameter of the conductive ball.

### BRIEF DESCRIPTION OF THE FIGURES

The invention will be better understood on reading the following description, which is given solely by way of example and with reference to the appended drawings, in which:

FIG. 1 is a side view of a microelectronic assembly according to one embodiment of the invention.

FIG. 2 is a detailed side view of an attachment member of the microelectronic assembly in FIG. 1. The edges of a conductive ball of the attachment member are shown in dotted lines where hidden.

FIG. 3 is a sectional view of the attachment member in FIG. 2.

FIG. 4 is a facing view of the volume of an adhesion material deposited for the manufacture of an attachment member from FIG. 2 (at the bottom) and a sectional view of a conductive ball of the attachment member in FIG. 2 (at the top). For greater clarity, the base of the adhesion material is shown in grey.

FIG. 5 shows three steps (A, B, and C) in a method for manufacturing the microelectronic assembly in FIG. 1.

### DETAILED DESCRIPTION

The following embodiments are examples. Although the description makes reference to one or more embodiments, this does not necessarily mean that each reference relates to the same embodiment, or that the features are applicable only to a single embodiment. Simple features of various embodiments may also be combined and/or interchanged in order to provide other embodiments.

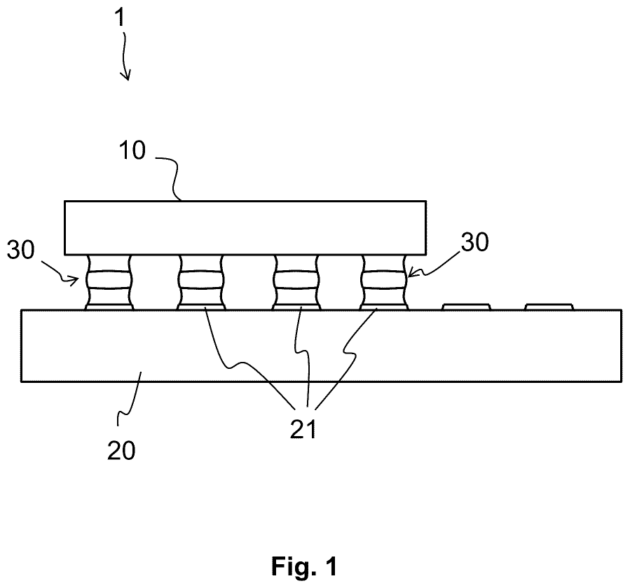

The invention relates to a microelectronic assembly 1 comprising a microelectronic component 10, a carrier 20 and a set of attachment members 30 bonding the microelectronic component 10 and the carrier 20 together, as shown in FIG. 1.

The microelectronic component 10 forms the upper portion of the assembly 1. The microelectronic component is notably a chip, a microprocessor, a dynamic random access memory, a microelectromechanical system (MEMS) or a flash memory.

The carrier 20 forms the lower portion of the assembly 1. The carrier 20 is notably a printed circuit, a ceramic substrate, an organic substrate resulting from additive manufacturing or any other carrier for conductive tracks.

The microelectronic component 10 and the carrier 20 each comprise connection pads 11, 21 in order to establish electrical connections between these elements. The attachment members 30 are arranged so as to connect the pads 11, 21 to each other. Thus, each attachment member 30 has a dual function of bonding the microelectronic component 10 to the carrier 20 and of electrically connecting these two elements 10, 20 together. It is therefore essential for each attachment member to withstand mechanical and thermal stresses in order to avoid, on the one hand, separation of the microelectronic component 10 from the carrier 20 and, on the other hand, the loss of electrical connections between these elements which can render the microelectronic assembly 1 non-functional.

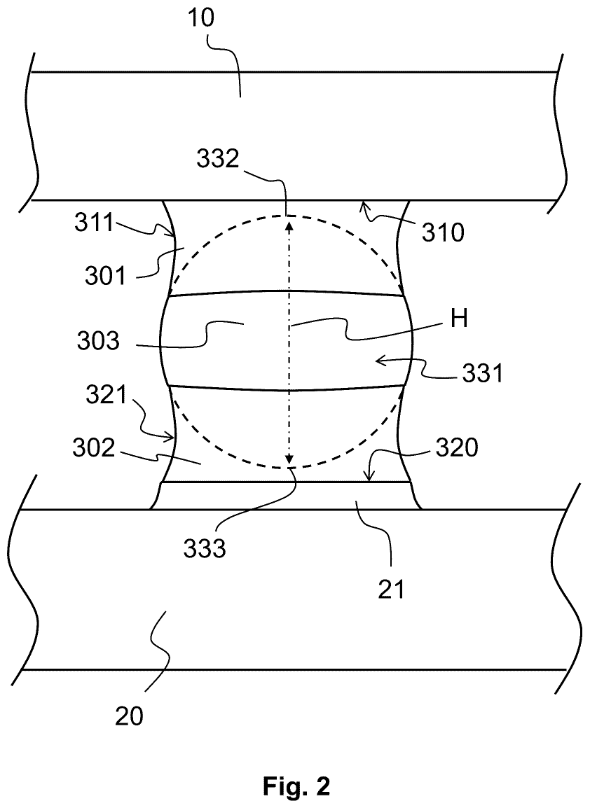

As shown in FIG. 2, each attachment member 30 comprises a first adhesion material 301, a second adhesion material 302 and a conductive ball 303 between the two.

The first and second adhesion materials 301, 302 are chosen notably from solders, notably tin-based solders, and conductive adhesives, notably adhesives based on an epoxy resin.

The first adhesion material 301 attaches the electronic component 10 to the conductive ball 303, and the second adhesion material 302 attaches the carrier 20 to the conductive ball 303.

The adhesion materials 301, 302 are arranged at the connection pads 11, 21 on the microelectronic component 10 and the carrier 20.

The first adhesion material 301 thus comprises an attachment surface 310 with the electronic component 10.

Similarly, the second adhesion material 302 comprises an attachment surface 320 with the carrier 20.

The invention uses a limited quantity of each of the adhesion materials 301, 302 during the manufacture of the assembly 1, as described in detail below.

This limited quantity of material means that the conductive ball 303 is thinly covered, in full or in part, or not covered at all, by the first and/or the second material 301, 302 in a central zone 331. Thus, as can be seen in FIG. 2, the conductive ball 303 can be partially covered by the two adhesion materials 301, 302.

The central zone 331 is notably the central third of the conductive ball 303. In the embodiment shown, the central third 331 of the conductive ball 303 is bare, i.e. it is not covered by the first or second adhesion material 301, 302. The central third 331 of the conductive ball 303 is the surface extending between the upper third and the lower third of the ball 303 along its height H. “Height of the conductive ball” means the diameter of the conductive ball 303 considered along an axis transverse to the assembly 1.

According to an advantageous embodiment of the invention, the conductive ball 303 is covered at most as far as the upper third of its height H by the first adhesion material 301, and at most as far as the lower third of its height H by the second adhesion material 302.

According to an alternative embodiment, the ball 303 is covered at least as far as the upper third of its height H by the first adhesion material 301, and/or at least as far as the lower third of its height H by the second adhesion material 302. In particular, the ball 303 is entirely covered by the first and second adhesion materials 301, 302. Notably, the covering of each of the materials 301, 302 stops, in particular substantially, at the equator of the ball 303 considered according to its height H. In these embodiments, the respective thickness of the adhesion materials 301, 302 in the central third 331 is thin, i.e. less than 10 nm, notably less than 7 nm, for example less than 5 nm. Thus, at least 95% of the volume of the first adhesion material 301 may be located between the microelectronic component 10 and the upper third of the height H of the ball 303, and at least 95% of the volume of the second adhesion material 302 may be located between the carrier 20 and the lower third of the height H of the conductive ball 303. Notably, this is at least 97% of their respective volumes, notably at least 99%. The presence of a covering in the central third of the conductive ball 303 despite a limited quantity of adhesion material 10, 20 used may notably be due to a capillary effect of the adhesion materials 301, 302 along the surface of the ball 303 during the manufacture of the assembly 1, as will be seen later.

The limited quantity of adhesion material 10, 20 in the assembly 1 can also give a particular shape to the first and second adhesion materials 301, 302. Thus, according to one embodiment of the invention, the first adhesion material 301 comprises a constriction 311 arranged facing the top 332 of the conductive ball 303 and the second adhesion material 301 comprises a constriction 321 arranged facing the base 333 of the conductive ball 303. The top 332 of the ball 303 is considered to be the highest point along the height H. The base 333 of the ball is considered to be the lowest point along the height H. These constrictions 311, 321 may notably be a consequence of the capillary effect of the adhesion materials 301, 302 along the surface of the conductive ball 303 during the manufacture of the assembly 1.

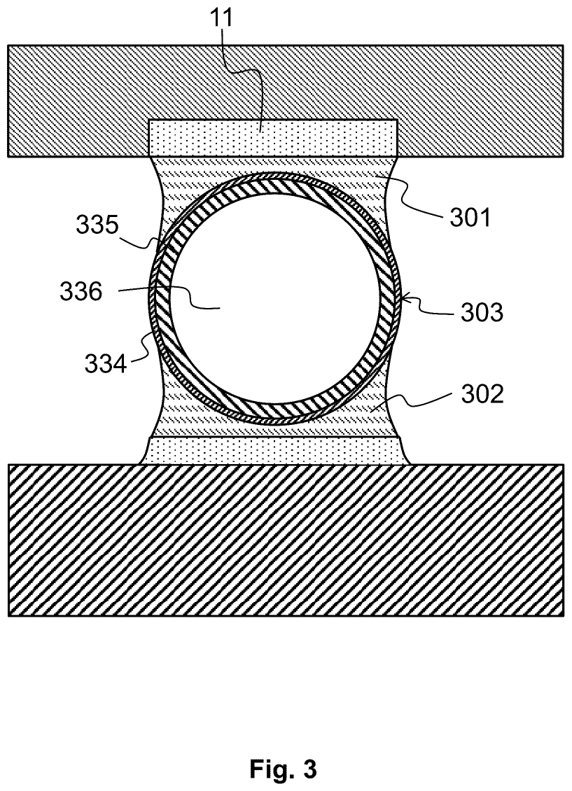

According to a particular embodiment of the invention, at least one of the attachment members 30 comprises a first adhesion material 301 and a second adhesion material 302, the respective volume of which corresponds to the volume of a truncated cone 340 comprising a recess 341, as shown in FIG. 3. Such a volume optimizes the adhesion of each adhesion material 301, 302 to the conductive ball 303 and to the microelectronic element 10 and to the carrier 20 respectively, while providing good thermal and mechanical resistance. The recess 341 is the seat for the conductive ball 303 in the adhesion material 301, 302. The diameter de of the base 342 of the truncated cone 340 is chosen notably in a range from a diameter of less than 5% of the diameter D of the conductive ball 303 to 10% of the diameter D. Notably, the diameter de is equal to the diameter D. The height hc of the truncated cone 340 is notably less than or equal to a third H_{1/3} of the height H of the conductive ball 303, and notably greater than or equal to a quarter of the height H. The diameter dₛ of the truncated top 343 of the cone 38 is notably less than or equal to the diameter des of the base of a spherical cap having a height that is one third of the height of the conductive ball 303, and notably greater than or equal to the diameter of the base of a spherical cap having a height that is one quarter of the height of the conductive ball 303. The diameter dₛ is less than the diameter de. The recess 341 notably has a volume less than or equal to the volume of a spherical cap having a height that is one third of the height of the conductive ball 303, and notably greater than or equal to the volume of a spherical cap having a height that is one quarter of the height of the conductive ball 303. Of course, the volume of the recess 341 is limited by the dimensions of the height hc of the truncated cone 340 and of the diameter dₛ of its top 343.

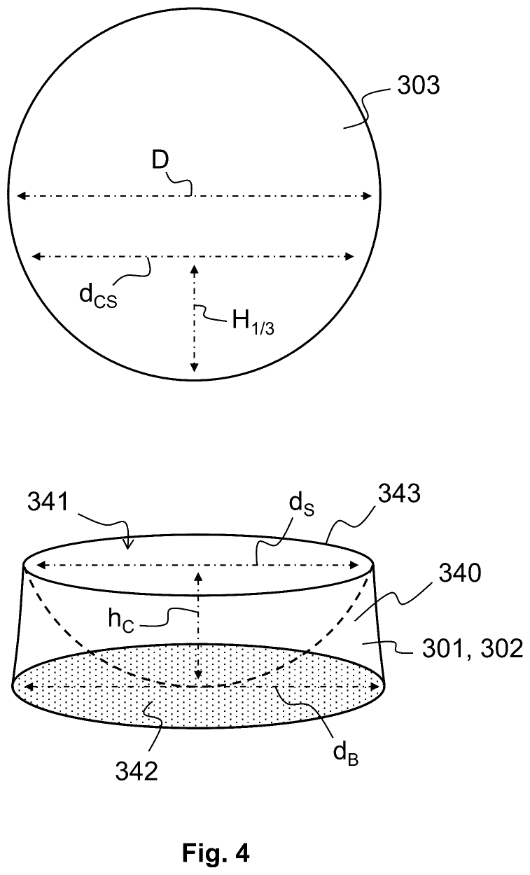

The conductive ball 303 is illustrated more clearly in FIG. 4. The conductive ball 303 is capable of conducting an electric current. The conductive ball 303 of an attachment member 30 comprises notably a hollow sphere 334 made of copper covered with a layer 335 of nickel, as shown in FIG. 4, which provides a diffusion barrier to prevent the copper from diffusing into the adhesion materials 301, 302. The conductive ball 303 thus has an empty core 336, which enhances its deformation properties compared to a solid or hollow sphere with a core, notably made of ceramic, metal or polymer. The deformation properties of the conductive ball 303 coupled with the limited quantity of adhesion material 301, 302 greatly multiplies the deformation properties of the attachment members 30 and thus their capacity to withstand mechanical and thermal forces.

According to a preferred embodiment of the invention, the thickness of the copper sphere 335 is less than or equal to 100 μm, notably less than or equal to 70 μm, particularly less than or equal to 50 μm, in particular less than or equal to 30 μm, more notably from 12 μm to 20 μm. Reducing the thickness of the copper sphere 335 increases the deformation capacity of the conductive ball, and therefore the resistance of the attachment member to mechanical and thermal forces.

The nickel layer 334 of the conductive ball 303 may notably be a layer of medium-phosphorus nickel. In particular, the phosphorus content in the medium-phosphorus nickel layer is less than or equal to 15% by weight of the medium-phosphorus nickel layer, notably less than or equal to 10%, more particularly from 7% to 10%.

According to a preferred embodiment of the invention, the thickness of the nickel layer is less than or equal to 10 μm, notably from 4 μm to 7 μm, thus providing the desired diffusion barrier effect.

According to one embodiment of the invention, the conductive ball 303 of an attachment member 30 may comprise a coating of a material chosen from the group consisting of gold, silver, platinum, palladium and an alloy of several of these materials. Such a coating provides good adhesion to the adhesion materials 301, 302. The coating is notably a flash coating. The thickness of the coating is notably less than 0.2 μm.

FIG. 4 also shows the connection pad 11 of the microelectronic element 10. Here the connection pad 11 is shown embedded in the microelectronic element 10, but any pad arrangement can be used.

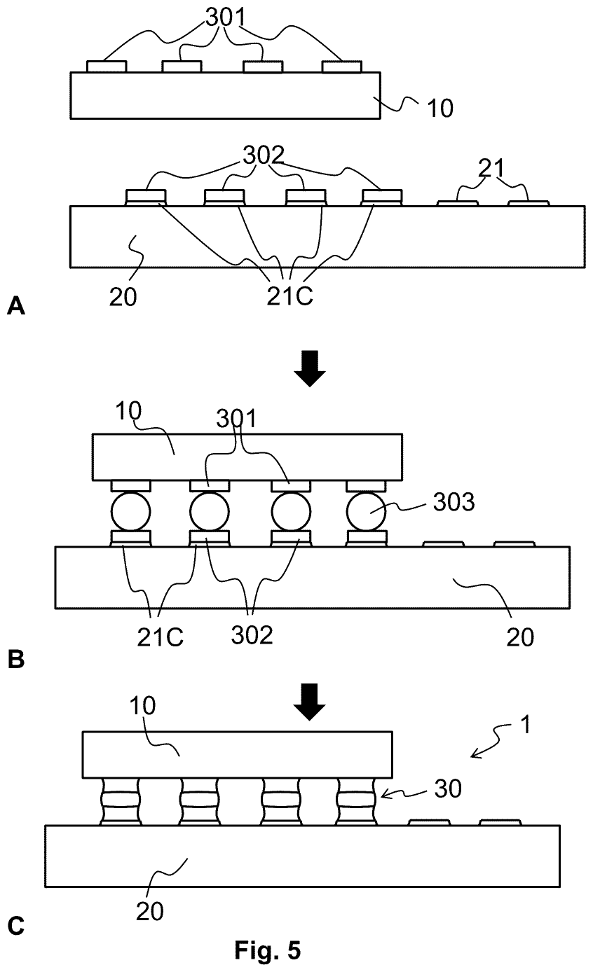

FIG. 5 shows different steps of a method of bonding a microelectronic component 10 to a carrier 20 using attachment members 30 in order to obtain an assembly as described above.

A first step, shown in FIG. 5A, relates to a first deposition of a first adhesion material 301 on each pad 11 of the microelectronic component 10 and of a second adhesion material 302 on each corresponding pad 21C of the carrier 20. During this step, the first and second adhesion materials 301, 302 are notably in paste form.

The carrier 20 comprises pads 21C referred to as “corresponding” pads. Indeed, the carrier may comprise more connection pads 21 than the microelectronic component 10, notably for bonding other microelectronic components. Thus, some or all of the pads 21 of the carrier 20 form the corresponding pads 21C. The pads 11 of the microelectronic component and the corresponding pads 21C of the carrier 20 are intended to be arranged to face one another and conductively connected to each other so as to form electrical bridges between the microelectronic component 10 and the carrier 20. A pad 11 of the microelectronic component 10 and its corresponding pad 21C of the carrier 20 are intended to be bonded together by an attachment member 30.

For at least one attachment member 30, the deposited volume of adhesion material 301, 302 is adjusted so that a central zone 331 of the surface of the conductive ball 303 is bare or at least partially covered with a thin layer of the first and/or second adhesion material 301, 302. Notably, the deposited volume corresponds to the volume of a truncated cone 340 comprising a recess 341, as described above. It is important to note that the shape of the adhesion materials 301, 302 deposited during this first step is not necessarily a truncated cone 340 comprising a recess 341. Indeed, during the subsequent heating step, the adhesion materials 301, 302 are liquefied before taking their final shape and solidifying. Thus, it is the volume, and therefore the quantity, of adhesion material 301, 302 that matters during this step. The deposited volume is adjusted to obtain the desired final shape.

This first step can notably be carried out using a first screen mask comprising openings adjusted to the position of the pads 11 of the microelectronic component 10 and a second screen mask comprising openings adjusted to the position of the pads 21 of the carrier 20. Typically, the adhesion materials 301, 302 are deposited in the various openings of the respective screen mask, then the screens are removed, leaving the desired volume of adhesion material 301, 302 on the pads 11, 21.

In a second step, conductive balls 303 are deposited on the second adhesion material 302 of the corresponding pads 21C of the carrier 20.

This second step can be carried out, for example, using a mesh or using a machine for depositing surface-mounted components. Thus, this step of arranging the conductive balls 303 can advantageously be carried out with conventional means, thereby optimizing production costs.

A third step is then carried out of aligning the pads 11 of the microelectronic component 10 with the corresponding pads 21C of the carrier 20, and bringing the first adhesion materials 301 of each pad 11 of the microelectronic component 10 into contact with the conductive balls 303. The result obtained is shown in FIG. 5B. As shown, each ball 303 is sandwiched between a first and a second adhesion material 301, 302. At this stage, the microelectronic component 10 has not yet been effectively bonded to the carrier 20.

To effect said bonding, a fourth step combining suitable heating and cooling is carried out. The heating and cooling values and times adjusted to suit each adhesion material are known to a person skilled in the art. This step firstly liquefies the first and second adhesion materials 301, 302, and subsequently cures them. The assembly 1 shown in FIG. 5C is thus obtained. The shape of the first and second adhesion materials is approximately that of a truncated cone comprising a recess, deformed by capillary effects occurring during the heating step.

During heating, the capillary effects cause the conductive balls 303 to be coated with the first and second materials 301, 302. This coating may be partial or total, as explained above.

During cooling, the second adhesion materials 302 bond the conductive ball 303 to the carrier 20 and the first adhesion materials 301 bond the conductive ball 303 to the microelectronic component 101, thus forming the various attachment members 30.

### Example: Stress Simulation

In this example, the inventors compared simulations carried out using Ansys® software between different types of attachment member connecting a microelectronic component to a carrier. A first comparative attachment member (1) was in the form of an Sn63Pb37 solder ball. A second comparative attachment member (2) included a hollow copper ball with a shell thickness of 25 μm and a large amount of Sn63Pb37 solder, equivalent for each pad to the volume of a straight circular cylinder 12 μm tall, including a recess corresponding to half the volume of the hollow ball. An attachment member according to the invention (3) included a hollow copper ball with a shell thickness of 25 μm and a small amount of Sn63Pb37 solder, equivalent for each pad to the volume of a truncated cone with a base having a diameter of 25 μm and a height of 8 μm, and a recess having the shape of a spherical cap having a height of 8 μm.

The results obtained are given in the following table:

| | Young's | | | | | |
|---|---|---|---|---|---|---|
| | modulus | | Copper | Maximum stress (MPa) | | |
| | of the | | shell | | Microelectronic- | Carrier- |
| Attachment | member | Solder | thickness | | component- | side |
| member | (GPa) | volume | (μm) | Ball | side solder | solder |
| 1 | 26 | High | — | — | 102 | 94 |
| 2 | 125 | High | 25 | 268 | 118 | 110 |
| 3 | 125 | low | 25 | 382 | 66 | 58 |

The results show that the use of a thin shell around the ball coupled with a smaller amount of solder reduces the stresses on the solder points by improving deformation of the ball, which absorbs more stress, and therefore a better resistance to thermal expansion and contractions of the attachment member.

1. A microelectronic assembly comprising a microelectronic component, a carrier and a set of attachment members bonding the microelectronic component to the carrier, each attachment member comprising a conductive ball bonded to the microelectronic component by a first adhesion material and to the carrier by a second adhesion material, wherein for at least one of the attachment members a central zone of the surface of the conductive ball considered along an axis transverse to the assembly is bare or partially or completely covered by a layer of the first adhesion material and/or a layer of the second adhesion material with a respective thickness of not more than 10 nm.

2. The microelectronic assembly as claimed in claim 1, wherein the microelectronic component forms the upper portion of the assembly and the carrier forms the lower portion of the assembly, wherein for at least one of the attachment members:
at least 95% of the volume of the first adhesion material is located between the microelectronic component and the upper third of the height of the conductive ball considered along an axis transverse to the assembly, and
at least 95% of the volume of the second adhesion material is located between the carrier and the lower third of the height of the conductive ball considered along an axis transverse to the assembly.

3. The microelectronic assembly as claimed in claim 1, wherein for at least one of the attachment members, the first adhesion material comprises a constriction arranged to face the top of the conductive ball and the second adhesion material comprises a constriction arranged to face the base of the conductive ball, the top and the base of the conductive ball being considered along an axis transverse to the assembly.

4. The microelectronic assembly as claimed in claim 1, wherein the microelectronic component forms the upper portion of the assembly and the carrier forms the lower portion of the assembly, wherein for at least one of the attachment members the volume of the first and second adhesion materials corresponds respectively to the volume of a truncated cone comprising a recess, said truncated cone preferably has a base having a diameter equal to the diameter of the conductive ball and a height one third of the diameter of said conductive ball and said recess being shaped as a spherical cap having a height that is one third of the diameter of the conductive ball.

5. The microelectronic assembly as claimed in claim 1, wherein for at least one of the attachment members, the conductive ball comprises a hollow copper sphere covered with a layer of nickel, preferably a layer of medium-phosphorus nickel, more preferably the phosphorus content is less than 15%.

6. The microelectronic assembly as claimed in claim 5, wherein the copper sphere has a thickness of less than 100 μm, preferably less than or equal to 50 μm, more preferably 15 μm to 20 μm.

7. The microelectronic assembly as claimed in claim 5, wherein the nickel layer has a thickness of less than 10 μm, preferably 4 μm to 7 μm.

8. The microelectronic assembly as claimed in claim 1, wherein for at least one of the attachment members, the conductive ball comprises a coating of a material selected from the group consisting of gold, silver, platinum, palladium and an alloy of several of these materials.

9. A method of bonding a microelectronic component to a carrier using attachment members of a microelectronic assembly as claimed in claim 1, the microelectronic component and the carrier each comprising a plurality of connection pads, the method comprising the following steps:
a) a first deposition of a first adhesion material on each pad of the microelectronic component and of a second adhesion material on each corresponding pad of the carrier,
b) a second deposition of a conductive ball on the second adhesion material of each corresponding pad of the carrier,
c) aligning the pads of the microelectronic component with the corresponding pads of the carrier, and bringing the first adhesion materials of each pad of the microelectronic component into contact with the conductive balls, and
d) suitably heating and then suitably cooling the assembly to form the attachment members by shaping and curing the first and second adhesion materials, thereby bonding the microelectronic component to the carrier,
wherein in the first deposition step a), for at least one of the attachment members the deposited volume of the first and second adhesion materials on the pads is adjusted so that in the heating step d) a central zone of the surface of the conductive ball considered along an axis transverse to the assembly is bare or partially or completely covered by a layer of the first adhesion material and/or a layer of the second adhesion material with a respective thickness of not more than 10 nm.

10. The bonding method as claimed in claim 9, wherein for at least one of the attachment members the deposited volume of the first and second adhesion materials on the pads corresponds to the volume of a truncated cone comprising a recess, said truncated cone preferably has a base having a diameter equal to the diameter of the conductive ball and a height one third of the diameter of said conductive ball and said recess being shaped as a spherical cap having a height that is one third of the diameter of the conductive ball.
